(19) United States
(12) Patent Application Publication
(10) Pub. No.: US 2006/0019501 A1
(43) Pub. Date: Jan. 26, 2006

(54) Methods of forming a thin layer including hafnium silicon oxide using atomic layer deposition and methods of forming a gate structure and a capacitor including the same

(75) Inventors: Beom-Jun Jin, Seoul (KR); Hong-Bae Park, Seoul (KR); Sang-Bom Kang, Seoul (KR); Yu-Gyun Shin, Gyeonggi-do (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 11/180,121

(22) Filed: Jul. 13, 2005

(30) Foreign Application Priority Data
Jul. 21, 2004 (KR) 2004-0056865

(51) Int. Cl. H01L 21/44; H01L 21/31; H01L 21/26

(52) U.S. Cl. 438/785; 438/798; 438/680; 438/685

(57) ABSTRACT

Methods of forming a thin film include applying a first reactant to a substrate, chemisorbing a first portion of the first reactant and physisorbing a second portion of the first reactant on the substrate, applying a first oxidizer to the substrate, chemically reacting the first oxidizer with the first portion of the first reactant to form a first solid material on the substrate, applying a second reactant to the first solid material, chemisorbing a first portion of the second reactant and physisorbing a second portion of the second reactant on the first solid material, applying a second oxidizer to the first solid material; and chemically reacting the second oxidizer with the first portion of the second reactant to form a second solid material on the first solid material.

### CROSS REFERENCE TO RELATED APPLICATION

This application claims priority to Korean Patent Application No. 2004-56865, filed on Jul. 21, 2004, the contents of which are herein incorporated by reference in its entirety.

### FIELD OF THE INVENTION

The present invention relates to methods of forming thin layers using an atomic layer deposition process and methods of forming gate structures and capacitors including the same. More particularly, the present invention relates to methods of forming solid thin layers including hafnium silicon oxide using an atomic layer deposition process, methods of forming gate structures including the same, and methods of forming capacitors including the same.

### BACKGROUND OF THE INVENTION

In general, a material having a high dielectric constant may maintain an equivalent oxide thickness of a thin layer and may also reduce a leakage current generated between a gate electrode and a channel or between an upper electrode and a lower electrode. Thus, materials having a high dielectric constant may be utilized to form a thin layer such as a gate insulation layer of a MOS transistor or a dielectric layer of a capacitor. A hafnium oxide (HfO₂) layer is an example of a thin layer having a high dielectric constant.

An example of a conventional method of forming a hafnium oxide layer is discussed in U.S. Pat. No. 6,348,386 to Gilmer. According to this method, when the hafnium oxide layer is formed, the hafnium oxide layer is crystallized at a temperature of about 300° C., such that a leakage current through the hafnium oxide layer can be increased. More specifically, when the hafnium oxide layer is used as a gate insulation layer and a polysilicon layer as a gate conductive layer is formed on the hafnium oxide layer, electron mobility may be decreased in a channel region due to penetration of impurities, such as boron.

Currently, a hafnium silicon oxide (HfSiO₂) layer may be used as an insulation layer in place of the hafnium oxide layer. The hafnium silicon oxide layer may have characteristics of about 0.9 times those of a silicon oxide layer. The hafnium silicon oxide layer may be formed by a sputtering process, a chemical vapor deposition (CVD) process, an atomic layer deposition (ALD) process, etc. However, when the hafnium silicon oxide layer is formed using a sputtering process, it may be difficult to produce the hafnium silicon oxide layer at manufacturing volumes. When the hafnium silicon oxide layer is formed employing a CVD process, it may be difficult to form a hafnium silicon oxide layer having a thickness of no more than about 50 Å. In particular, when the ratio between a hafnium precursor and a silicon precursor used in the CVD process slightly varies, the content of silicon may vary. Thus, it may be difficult to control a composition ratio between hafnium and silicon in the hafnium silicon oxide layer.

On the contrary, when the hafnium silicon oxide layer is formed using an ALD process, it may allow better control of the composition ratio between hafnium and silicon in the hafnium silicon oxide layer as well as the thickness of the hafnium silicon oxide layer, and may further enable better step coverage to the hafnium silicon oxide layer.

Examples of conventional methods of forming a hafnium silicon oxide layer are discussed in U.S. Patent Application Publication No. 2003-232506, Japanese Patent Laid Open Publication No. 2003-347297, and Korean Patent Laid Open Publication Nos. 2002-32054 and 2001-35736.

U.S. Patent Application Publication No. 2003-232506 discusses a method of forming a hafnium silicon oxide layer using tetrakis diethyl amino hafnium (TDEAH) as a hafnium precursor, and tetrakis dimethyl amino silicon (TDMAS) as a silicon precursor, without any mention of an ALD process.

Japanese Patent Laid Open Publication No. 2003-347297 discusses a method of controlling a composition ratio between hafnium and silicon in a hafnium silicon oxide layer, which uses TDEAH as a hafnium precursor and a tetra methoxy silane (TMOS) as a silicon precursor, by controlling the number of times that the TDEAH and the TMOS are introduced in forming a hafnium silicon oxide layer by an ALD process.

Korean Patent Laid Open Publication No. 2002-32054 discusses a method of forming a hafnium silicon oxide layer by reacting a silicon compound such as SiH₄, Si₂H₆, SiCl₂H₂, and the like, with a hafnium oxide layer.

Korean Patent Laid Open Publication No. 2001-35736, which corresponds to U.S. patent application Ser. No. 09/872,203, filed on May 31, 2001, discusses a method of forming a hafnium silicon oxide layer, without further discussion of a hafnium precursor and a silicon precursor.

In the above-mentioned conventional methods, however, the conventional hafnium precursor and the conventional silicon precursor used for reactants in forming the hafnium silicon oxide layer by an ALD process may not be diverse. In particular, the conventional hafnium precursor and the conventional silicon precursor may not exhibit a desirable reactivity with respect to each other.

### SUMMARY OF THE INVENTION

Embodiments of the present invention provide methods of forming thin layers including hafnium silicon oxide utilizing an atomic layer deposition (ALD) process.

In particular, embodiments of the present invention provide methods of forming a thin film including applying a first reactant including a hafnium precursor to a substrate, chemisorbing a first portion of the first reactant and physisorbing a second portion of the first reactant on the substrate, applying a first oxidizer to the substrate, chemically reacting the first oxidizer with the first portion of the first reactant to form a first solid material including hafnium oxide on the substrate, applying a second reactant including a silicon precursor to the first solid material, chemisorbing a first portion of the second reactant and physisorbing a second portion of the second reactant on the first solid material, applying a second oxidizer to the first solid material; and chemically reacting the second oxidizer with the first portion of the second reactant to form a second solid material including silicon oxide on the first solid material, wherein the method further employs an ALD process to form the thin layer including the first and second solid materials. In some embodiments, the hafnium precursor includes tetrakis ethyl methyl amino hafnium (TEMAH). In some embodiments, the silicon precursor includes tetrakis ethyl methyl amino silicon (TEMAS). In further embodiments, a solid thin layer including hafnium silicon oxide is formed employing TEMAH and TEMAS as hafnium and silicon precursors, respectively.

Further embodiments of the present invention provide methods of forming a gate structure including a thin layer including hafnium silicon oxide. In some embodiments, methods of forming the gate structure include: a) forming a gate insulation layer on a substrate, wherein the methods of forming the gate insulation layer include: (i) applying a first reactant including a hafnium precursor to a substrate, (ii) chemisorbing a first portion of the first reactant and physisorbing a second portion of the first reactant on the substrate, (iii) applying a first oxidizer to the substrate, (iv) chemically reacting the first oxidizer with the first portion of the first reactant to form a first solid material including hafnium oxide on the substrate, (v) applying a second reactant including a silicon precursor to the first solid material, (vi) chemisorbing a first portion of the second reactant and physisorbing a second portion of the second reactant on the first solid material, (vi) applying a second oxidizer to the first solid material, and (vii) chemically reacting the second oxidizer with the first portion of the second reactant to form a second solid material including silicon oxide on the first solid material, wherein the method includes an ALD process to form the gate insulation layer including hafnium silicon oxide on the substrate; b) forming a gate conductive layer on the gate insulation layer; and c) sequentially patterning the gate conductive layer and the gate insulation layer to form a gate structure including the gate conductive layer pattern and the gate insulation layer pattern. In some embodiments, the hafnium precursor comprises tetrakis ethyl methyl amino hafnium (TEMAH, Hf[NC₂H₅CH₃]₄). In some embodiments, the silicon precursor comprises tetrakis ethyl methyl amino silicon (TEMAS, Si[N(CH₃)C₂H₅]₄).

Embodiments of the present invention further provide methods of forming a capacitor including a thin layer including hafnium silicon oxide. In some embodiments, methods of forming a capacitor include: a) forming a lower electrode on a substrate; b) forming a dielectric layer including hafnium silicon oxide on the lower electrode, wherein the method includes (i) applying a first reactant including a hafnium precursor to a substrate; (ii) chemisorbing a first portion of the first reactant and physisorbing a second portion of the first reactant on the substrate; (iii) applying a first oxidizer to the substrate; (iv) chemically reacting the first oxidizer with the first portion of the first reactant to form a first solid material including hafnium oxide on the substrate; (v) applying a second reactant including a silicon precursor to the first solid material; (vi) chemisorbing a first portion of the second reactant and physisorbing a second portion of the second reactant on the first solid material; (vi) applying a second oxidizer to the first solid material; and (vii) chemically reacting the second oxidizer with the first portion of the second reactant to form a second solid material including silicon oxide on the first solid material, wherein the method includes an ALD process to form a dielectric layer including hafnium silicon oxide on the lower electrode; and c) forming an upper electrode on the dielectric layer. In some embodiments, the hafnium precursor includes tetrakis ethyl methyl amino hafnium (TEMAH, Hf[NC₂H₅CH₃]₄). In some embodiments, the silicon precursor includes tetrakis ethyl methyl amino silicon (TEMAS, Si[N(CH₃)C₂H₅]₄).

### BRIEF DESCRIPTION OF THE DRAWINGS

FIGS. 1 through 8 present cross sectional views illustrating methods of forming a thin layer using an ALD process according to some embodiments of the present invention;

FIGS. 9 and 10 present cross sectional views illustrating methods of forming a gate structure according to some embodiments of the present invention;

FIG. 11 presents a cross sectional view illustrating methods of forming a capacitor according to some embodiments of the present invention; and

FIG. 12 presents a graph illustrating thickness variances of a solid thin layer including hafnium silicon oxide formed using a method according to some embodiments of the present invention and a hafnium oxide layer formed using TEMAH and ozone.

### DETAILED DESCRIPTION OF EMBODIMENTS ACCORDING TO THE INVENTION

The present invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art.

The terminology used herein is for the purpose of describing particular embodiments only and is not intended to be limiting of the invention. As used herein, the singular forms “a”, “an” and “the” are intended to include the plural forms as well, unless the context clearly indicates otherwise. Also, as used herein, the term “and/or” includes any and all combinations of one or more of the associated listed items.

Unless otherwise defined, all terms (including technical and scientific terms) used herein have the same meaning as commonly understood by one of ordinary skill in the art to which this invention pertains. All publications, patent applications, patents, and other references mentioned herein are incorporated by reference in their entirety.

Moreover, it will be understood that steps comprising the methods provided herein can be performed independently or at least two steps can be combined. Additionally, steps comprising the methods provided herein, when performed independently or combined, can be performed at the same temperature and/or atmospheric pressure or at different temperatures and/or atmospheric pressures without departing from the teachings of the present invention.

It will be further understood that the terms “comprises,” “includes”, “including” and/or “comprising,” when used in this specification, specify the presence of stated features, steps, operations, elements, and/or components, but do not preclude the presence or addition of one or more other features, steps, operations, elements, components, and/or groups thereof.

In the drawings, the thickness of layers and regions may be exaggerated for clarity. It will be understood that when a layer is referred to as being “on” another layer or element, it can be directly on the other layer, or intervening layers may also be present. Alternatively, when an element is described as being “directly on” another element, no intervening elements are present between the elements. Additionally, like numbers refer to like elements throughout.

Embodiments of the present invention are further described herein with reference to cross-section illustrations that are schematic illustrations of idealized embodiments of the present invention. As such, variations from the shapes of the illustrations as a result, for example, of manufacturing techniques and/or tolerances, are to be expected. In particular, the regions illustrated in the figures are schematic in nature and their shapes are not intended to illustrate the precise shape of a region of a device and are not intended to limit the scope of the present invention.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

As will be appreciated by one of skill in the art, the present invention may be embodied as compositions and devices including the compositions as well as methods of making and using such compositions and devices. Moreover, each embodiment described and illustrated herein includes its complementary conductivity type embodiment as well.

According to some embodiments, the present invention provides methods of forming solid thin layers including hafnium silicon oxide.

Referring to FIG. 1, in some embodiments, a semiconductor substrate 100 is loaded into a chamber 10. When the chamber 10 has a temperature of below about 150° C., reactants may have insufficient reactivity. Further, when the chamber 10 has a temperature of above about 400° C., the layer may be rapidly crystallized and have characteristics associated with a CVD process. Thus, in some embodiments, the chamber 10 has a temperature in a range of about 150° C. to about 400° C. In other embodiments the temperature is in a range of about 250° C. to about 350° C., and in other embodiments, the temperature is about 300° C. When the chamber has a temperature of about 300° C., the layer may have characteristics associated with an ALD process.

In some embodiments, a first reactant including a hafnium precursor may be introduced into the chamber 10 for a time in a range of about 0.5 seconds to about 3 seconds, and in other embodiments, about 1 second. An example of the first reactant includes, but is not limited to, tetrakis ethyl methyl amino hafnium (TEMAH, Hf[NC₂H₅CH₃]₄). TEMAH may be applied to a surface of the semiconductor substrate 100 to chemisorb a first portion 120 of TEMAH and physisorb a second portion of TEMAH on the semiconductor substrate 100.

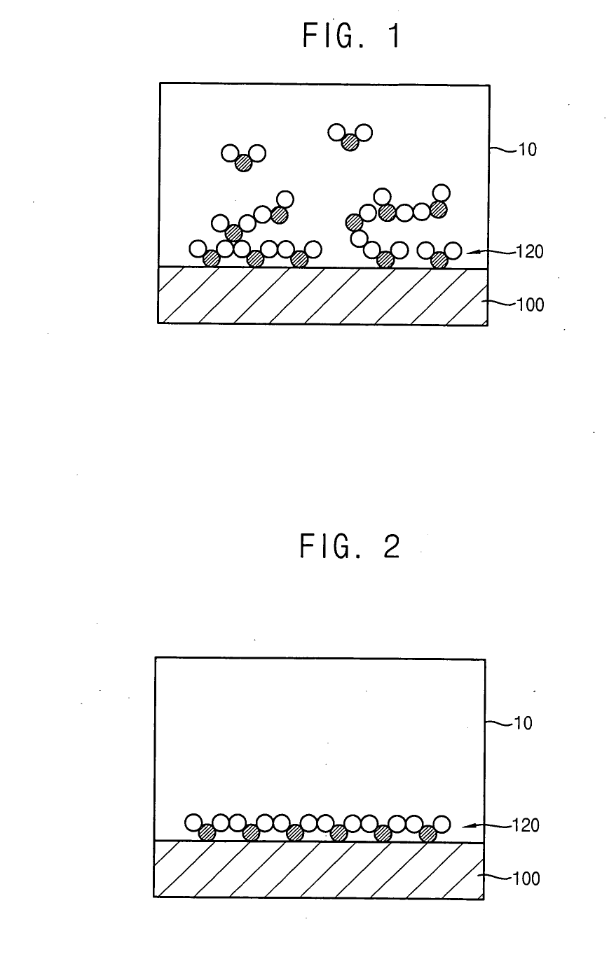

Referring to FIG. 2, a first purge gas such as an inactive gas including argon, nitrogen, neon, helium, carbon dioxide or mixtures thereof, and in some embodiments, argon gas, is introduced into the chamber 10 for a time in a range of about 0.5 seconds to about 3 seconds, and in some embodiments, about 1 second, to remove the second portion of TEMAH. More specifically, CH radicals in TEMAH may be chemically reacted with the first purge gas to remove the second portion of TEMAH from the semiconductor substrate 100. Hafnium (Hf) and nitrogen (N) may not react with the first purge gas so that the first portion of TEMAH chemisorbed on the semiconductor substrate 100 is maintained. Alternatively, vacuum may be provided to the chamber 10 to remove the CH radicals from the semiconductor substrate 100.

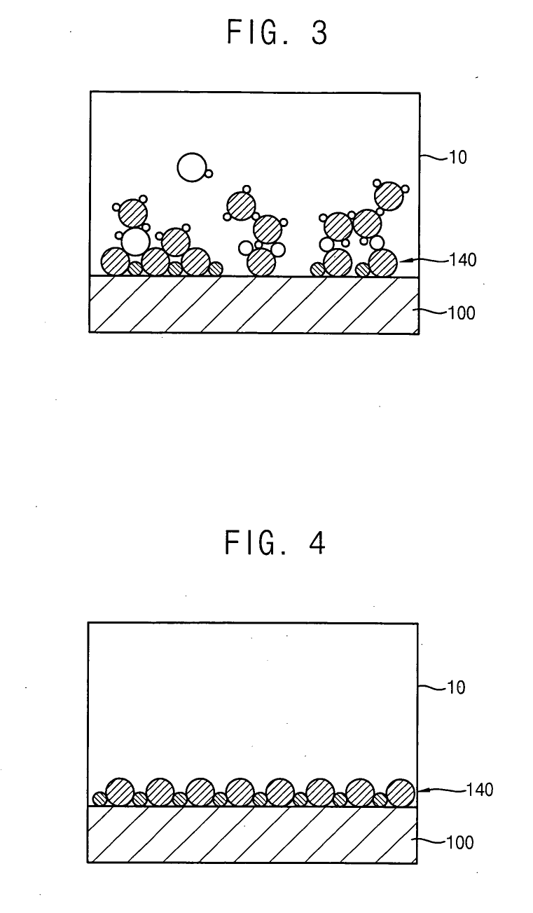

Referring to FIG. 3, a first oxidizer is introduced into the chamber 10 for a time in a range of about 1 second to about 5 seconds, and in some embodiments, about 3 seconds. Examples of the first oxidizer include O₃, H₂O, H₂O₂, CH₃OH, C₂H₅OH and the like. The oxidizers may be used alone or in a combination thereof. In some embodiments, O₃ is used as the first oxidizer. The first oxidizer may be applied to the surface of the semiconductor substrate 100 to oxidize hafnium or nitrogen chemisorbed on the semiconductor substrate 100. Since TEMAH has a hydrophilic property, the oxidation process may be readily generated. As a result, a first solid material 140 including hafnium oxide is formed on the semiconductor substrate 100. When nitrogen is chemisorbed on the semiconductor substrate 100, the first solid material 140 includes nitrogen as well as hafnium oxide.

Referring to FIG. 4, a second purge gas such as an inactive gas including argon, nitrogen, neon, helium, carbon dioxide or mixtures thereof, and in some embodiments, argon gas, is introduced into the chamber 10 for a time in a range of about 1 second to about 5 seconds, and in some embodiments, about 3 seconds, to remove a remaining first oxidizer in the chamber 10.

When the introduction of TEMAH, the first purge gas, the oxidizer and the second purge gas are performed more than once, the first solid material 140 including the hafnium oxide and further having a desired thickness may be formed on the semiconductor substrate 100.

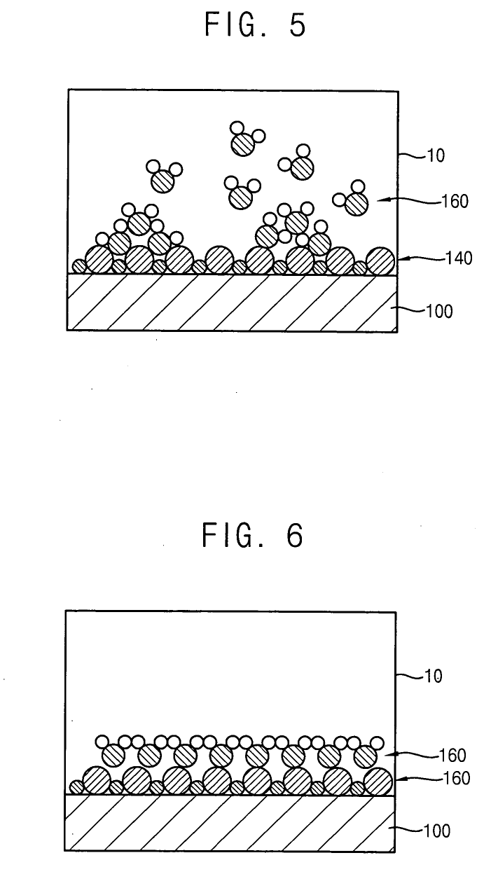

Referring to FIG. 5, a second reactant including a silicon precursor is introduced into the chamber 10 for a time in a range of about 0.5 seconds to about 3 seconds, and in some embodiments, about 1 second. Examples of the second reactant include, but are not limited to, tetrakis ethyl methyl amino silicon (TEMAS, Si[N(CH₃)C₂H₅]₄). In some embodiments, TEMAS is applied to a surface of the first solid material 140 to chemisorb a first portion 160 of TEMAS and physisorb a second portion of TEMAS on the first solid material 140.

Referring to FIG. 6, a third purge gas such as an inactive gas including argon, nitrogen, neon, helium, carbon dioxide or mixtures thereof, and in some embodiments, argon gas, is introduced into the chamber 10 for a time in a range of about 0.5 seconds to about 3 seconds, and in some embodiments, about 1 second, to remove the second portion of TEMAS. More specifically, CH radicals in TEMAS may be chemically reacted with the third purge gas to remove the second portion of TEMAS from the first solid material 140. Silicon (Si) may not react with the purge gas, such that the first portion of TEMAS chemisorbed on the first solid material 140 is maintained. Alternatively, vacuum may be provided to the chamber 10 for a time in a range of about 2 seconds to about 3 seconds to remove the CH radicals from the first solid material 140.

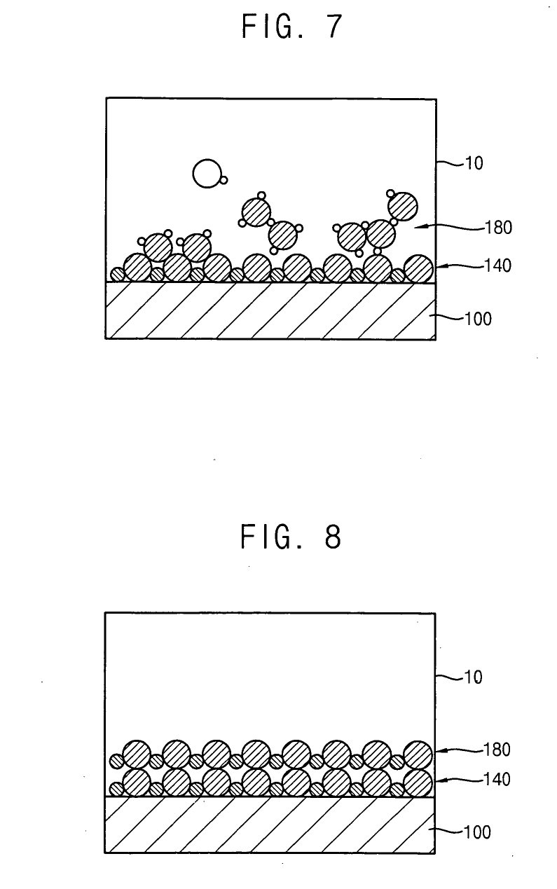

Referring to FIG. 7, a second oxidizer is introduced into the chamber 10 for a time in a range of about 1 second to about 5 seconds, and in some embodiments, about 3 seconds. Examples of the second oxidizer include O₃, H₂O, H₂O₂, CH₃OH, C₂H₅OH and the like. The oxidizers may be used alone or in a combination thereof. In some embodiments, O₃ is used as the second oxidizer. The second oxidizer may be applied to the surface of the first solid material 140 to oxidize silicon chemisorbed on the first solid material 140. Since TEMAS can exhibit hydrophilic properties, the oxidation process may be readily generated. As a result, a second solid material 180 including silicon oxide is formed on the first solid material 140. When nitrogen is chemisorbed on the first solid material 140, the second solid material 180 includes nitrogen as well as silicon oxide.

Referring to FIG. 8, a fourth purge gas such as an inactive gas including argon, nitrogen, neon, helium, carbon dioxide or mixtures thereof, and in some embodiments, argon gas, is introduced into the chamber 10 for a time in a range of about 1 second to about 5 seconds, and in some embodiments, about 3 seconds, to remove a remaining second oxidizer in the chamber 10. Additionally, when the introduction of TEMAS, the first, second, third and fourth purge gases and the first and second oxidizers are performed more than once, the second solid material 180 including silicon oxide and further having a desired thickness may be formed on the first solid material 140.

Further, when the introduction of TEMAH, the first purge gas, the first oxidizer, the second purge gas, TEMAS, the third purge gas, the second oxidizer and the fourth purge gas are carried out more than once, the solid thin layer including hafnium silicon oxide may be formed on the semiconductor substrate 100. Moreover, the number of times in which TEMAH, the first purge gas, the first oxidizer, the second purge gas, TEMAS, the third purge gas, the second oxidizer and the fourth purge gas are introduced may be adjusted to control the composition ratio between hafnium and silicon.

In some embodiments, the solid thin layer including hafnium silicon oxide is readily formed using TEMAH and TEMAS, which exhibit desirable reactivity. The number of times that the first solid material including hafnium oxide and the second solid material including silicon oxide are formed may be adjusted in order to obtain the solid thin layer including hafnium silicon oxide further having a desirable composition ratio between hafnium and silicon.

According to some embodiments, the present invention provides methods of forming a gate structure.

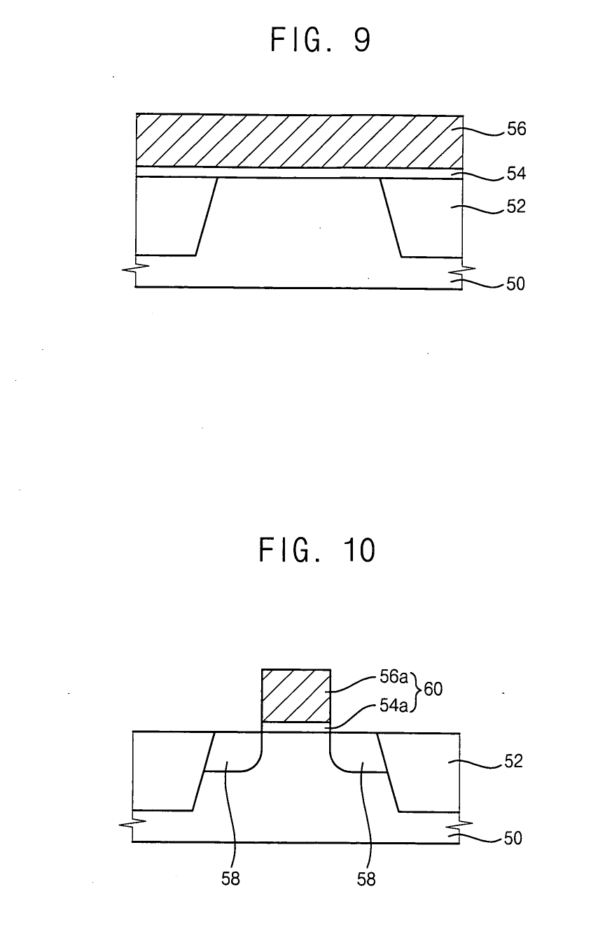

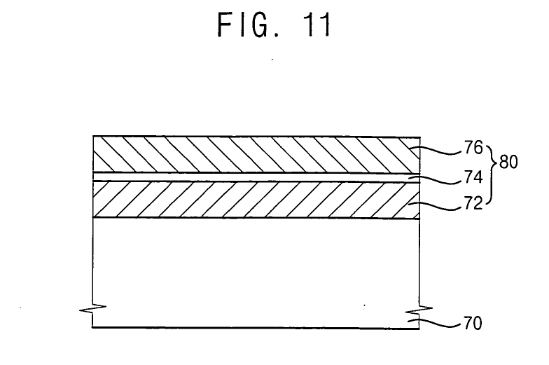

Referring to FIG. 9, a trench is formed at a surface portion of a semiconductor substrate 50 such as a silicon substrate. The trench is filled with an isolation layer 52, thus defining an active region and a field region on the semiconductor substrate 50.

Similar methods as described above relating to methods of forming a solid thin layer including hafnium silicon oxide can be performed on the semiconductor substrate 50 to form a gate insulation layer 54 including hafnium silicon oxide on the semiconductor substrate 50. In this instance, the number of times that a first solid material including hafnium oxide and a second solid material including silicon oxide are formed may be adjusted in order to obtain the gate insulation layer 54 including hafnium silicon oxide having a desirable composition ratio between hafnium and silicon.

A gate conductive layer 56 may be formed on the gate insulation layer 54 by employing a CVD process. Examples of the gate conductive layer 56 are polysilicon, metal, metal nitride and the like.

Referring to FIG. 10, the gate conductive layer 56 and the gate insulation layer 54 are partially etched to form a gate structure 60 including a gate insulation layer pattern 54a and a gate conductive layer pattern 56a. Source/drain regions 58 are formed on surface portions of the semiconductor substrate 50 adjacent to the gate structure 60. The source/drain regions 58 may be formed before forming the gate insulation layer 54 or after forming the gate structure 60. Additionally, a gate spacer may be formed on a sidewall of the gate structure 60.

In some embodiments, the solid thin layer including hafnium silicon oxide formed using TEMAH and TEMAS, which exhibit desirable reactivity to each other, is employed in the gate insulation layer pattern 54a. Accordingly, the gate insulation layer pattern 54a may have a thin equivalent oxide thickness (EOT). Also, any leakage current generated between the gate conductive layer pattern 56a and the semiconductor substrate 50, if any, may be reduced.

According to some embodiments, the present invention provides methods of forming a capacitor.

Referring to FIG. 11, a semiconductor substrate 70, similar to the semiconductor substrates described above, is prepared. When a semiconductor device using the semiconductor substrate 70 is a dynamic random access memory (DRAM) device, a semiconductor structure such as a gate structure, a bit line, a word line, and the like may be formed on the semiconductor substrate 70.

A lower electrode 72 may be formed on the semiconductor substrate 70 having the semiconductor structure provided by a CVD process. Examples of the lower electrode 72 include polysilicon, metal, metal nitride, and the like. Additionally, to increase an effective area of the lower electrode 72, the lower electrode 72 may be patterned to form a cylindrical lower electrode.

Methods similar to those described above for the preparation of a solid thin layer including hafnium silicon oxide can be performed to form a dielectric layer 74 including hafnium silicon oxide on the lower electrode 72. The number of times that a first solid material including hafnium oxide and a second solid material including silicon oxide are formed may be adjusted in order to obtain the dielectric layer 74 including hafnium silicon oxide and further having a desirable composition ratio between hafnium and silicon.

An upper electrode 76 may be formed on the dielectric layer 74 by a CVD process to provide a capacitor 80 including the lower electrode 72, the dielectric layer 74 including hafnium silicon oxide and the upper electrode. Examples of a material for the upper electrode 76 include polysilicon, metal, metal nitride, and the like.

According to some embodiments, the solid thin layer including hafnium silicon oxide that is formed using TEMAH and TEMAS, which exhibit desirable reactivity to each other, is employed in the dielectric layer 74. Accordingly, the dielectric layer 74 may have a thin EOT.

### EXAMPLE

Evaluation of Thickness Variances in Accordance with Deposition Cycles

Thickness variances of a solid thin layer including hafnium silicon oxide and a hafnium oxide layer formed using methods disclosed herein were evaluated.

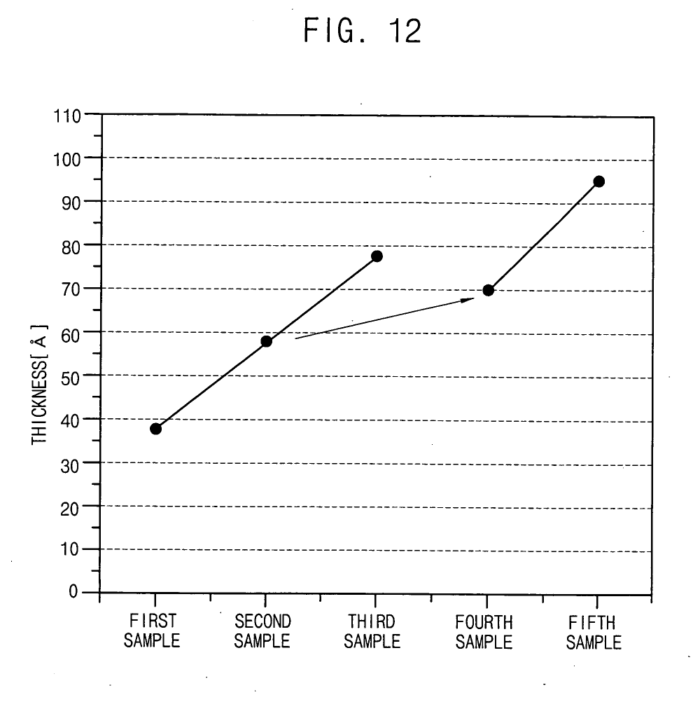

Referring to FIG. 12, a first sample was formed by performing thirty cycles of an ALD process that included introducing TDEAH for a time of 1 second, introducing an argon gas for a time of 1 second, introducing an ozone gas for a time of 3 seconds and introducing an argon gas for a time of 3 seconds. A second sample was formed by performing sixty cycles of an ALD process identical to that for forming the first sample. A third sample was formed by performing ninety cycles of an ALD process identical to that for forming the first sample.

A fourth sample was formed by performing sixty cycles of an ALD process that included introducing TEMAH for a time of 1 second, introducing an argon gas for a time of 1 second, introducing an ozone gas for a time of 3 seconds, introducing TEMAS for a time of 1 second, introducing an argon gas for a time of 1 second, introducing an ozone gas for a time of 3 seconds and introducing an argon gas for a time of 3 seconds. A fifth sample was formed by performing ninety cycles of an ALD process substantially identical to that for forming the fourth sample.

Each of the first, second and third samples that were formed by performing one cycle of the ALD process had a thickness of 0.66 Å. In particular, each of the oxide layers formed on interfaces in the first, second and third samples had a thickness of 17.8 Å. Thus, the first sample had a thickness of 37.6 Å, the second sample had a thickness of 57.4 Å and the third sample had a thickness of 77.2 Å.

Each of the fourth and fifth samples that were formed by performing one cycle of the ALD process had a thickness of 0.82 Å. In particular, each of the oxide layers formed on interfaces in the fourth and fifth samples had a thickness of 20.9 Å. Thus, the fourth sample had a thickness of 70.1 Å and the fifth sample had a thickness of 94.7 Å.

It should be noted that a hafnium silicon oxide layer corresponding to the fourth and fifth samples had a thickness of 1.25 times that of a hafnium oxide layer corresponding to the first, second and third samples. It should be further noted that the hafnium silicon oxide layer was formed by the ALD process using TEMAH and TEMAS. Additionally, it can be noted that a composition ratio between hafnium and silicon in the hafnium silicon oxide layer was controlled by varying the number of times that a first solid material including hafnium oxide and a second solid material including silicon oxide were formed, where the resultant hafnium silicon oxide layers exhibited thicknesses different from each other.

According to embodiments of the present invention, the solid thin layer including hafnium silicon oxide may be formed using TEMAH as a hafnium precursor and TEMAS as a silicon precursor where these compounds demonstrate desirable reactivity to each other. In particular, the hafnium silicon oxide layer having a composition ratio between hafnium and silicon may be obtained by varying the number of times that a first solid material including hafnium oxide and a second solid material including silicon oxide are formed. Moreover, the hafnium silicon oxide layer may be used as the gate insulation layer or the dielectric layer. Thus, a semiconductor device including the gate insulation layer or the dielectric layer may demonstrate improved electrical characteristics.

Having described various embodiments of the present invention, it is noted that modifications and variations can be made by those having ordinary skill in the art in light of the above teachings. It is therefore to be understood that changes may be made with respect to particular embodiments of the present invention disclosed herein which are within the scope and spirit of the invention outlined by the appended claims.

What is claimed is:

1. A method of forming a thin film comprising:
a) applying a first reactant comprising a hafnium precursor to a substrate;
b) chemisorbing a first portion of the first reactant and physisorbing a second portion of the first reactant on the substrate;
c) applying a first oxidizer to the substrate;
d) chemically reacting the first oxidizer with the first portion of the first reactant to form a first solid material comprising hafnium oxide on the substrate;
e) applying a second reactant comprising a silicon precursor to the first solid material;
f) chemisorbing a first portion of the second reactant and physisorbing a second portion of the second reactant on the first solid material;
g) applying a second oxidizer to the first solid material; and
h) chemically reacting the second oxidizer with the first portion of the second reactant to form a second solid material comprising silicon oxide on the first solid material,
wherein the method further comprises an atomic layer deposition (ALD) process to form a thin layer comprising the first and second solid materials.

2. The method of claim 1, wherein the hafnium precursor comprises tetrakis ethyl methyl amino hafnium (TEMAH, Hf[NC₂H₅CH₃]₄).

3. The method of claim 1, wherein the silicon precursor comprises tetrakis ethyl methyl amino silicon (TEMAS, Si[N(CH₃)C₂H₅]₄).

4. The method of claim 1, wherein the first and second oxidizers independently comprise O₃, H₂O, H₂O₂, CH₃OH, C₂H₅OH or combinations thereof.

5. The method of claim 1, wherein the solid thin layer comprises a gate insulation layer.

6. The method of claim 1, wherein the solid thin layer comprises a dielectric layer.

7. The method of claim 1, wherein the method is performed at a temperature in a range of about 150° C. to about 400° C.

8. The method of claim 1, wherein (a) through (d) are performed at least once.

9. The method of claim 1, wherein (e) through (h) are performed at least once.

10. The method of claim 7, wherein the method is performed at least once.

11. The method of claim 1, further comprising chemisorbing nitrogen on the first solid material.

12. The method of claim 1, further comprising:
removing the physisorbed second portion of the first reactant from the substrate;
removing a portion of unreacted first oxidizer from the substrate;
removing the physisorbed second portion of the second reactant from the first solid material; and
removing a portion of unreacted second oxidizer from the substrate.

13. The method of claim 12, wherein the first and/or second oxidizers and/or physisorbed second portion of the first and/or second reactants are removed using an inactive gas independently comprising argon, nitrogen, neon, helium, carbon dioxide or mixtures thereof.

14. A method of forming a gate structure comprising:
a) forming a gate insulation layer on a substrate, wherein the method of forming the gate insulation layer comprises:
(i) applying a first reactant comprising a hafnium precursor to a substrate;
(ii) chemisorbing a first portion of the first reactant and physisorbing a second portion of the first reactant on the substrate;
(iii) applying a first oxidizer to the substrate;
(iv) chemically reacting the first oxidizer with the first portion of the first reactant to form a first solid material comprising hafnium oxide on the substrate;
(v) applying a second reactant comprising a silicon precursor to the first solid material;
(vi) chemisorbing a first portion of the second reactant and physisorbing a second portion of the second reactant on the first solid material;
(vi) applying a second oxidizer to the first solid material; and
(vii) chemically reacting the second oxidizer with the first portion of the second reactant to form a second solid material comprising silicon oxide on the first solid material, wherein the method comprises an atomic layer deposition (ALD) process to form the gate insulation layer comprising hafnium silicon oxide on the substrate;
b) forming a gate conductive layer on the gate insulation layer; and
c) sequentially patterning the gate conductive layer and the gate insulation layer to form a gate structure comprising the gate conductive layer pattern and the gate insulation layer pattern.

15. The method of claim 14, wherein the hafnium precursor comprises tetrakis ethyl methyl amino hafnium (TEMAH, Hf[NC₂H₅CH₃]₄).

16. The method of claim 14, wherein the silicon precursor comprises tetrakis ethyl methyl amino silicon (TEMAS, Si[N(CH₃)C₂H₅]₄).

17. The method of claim 14, wherein the method of forming the gate insulation layer further comprises:
a) removing the second portion of the first reactant from the substrate;
b) removing a portion of unreacted first oxidizer from the substrate;
c) removing the second portion of the second reactant; and
d) removing a portion of unreacted second oxidizer from the substrate, wherein (a) through (d) are performed using an inactive gas independently comprising argon, nitrogen, neon, helium, carbon dioxide or mixtures thereof.

18. The method of claim 14, wherein the first and second oxidizers independently comprise O₃, H₂O, H₂O₂, CH₃OH, C₂H₅OH or combinations thereof.

19. The method of claim 14, wherein the method is performed at a temperature in a range of about 150° C. to about 400° C.

20. The method of claim 14, wherein (i) through (iv) and/or (v) through (vii) are performed at least once.

21. A method of forming a capacitor comprising:
a) forming a lower electrode on a substrate;
b) forming a dielectric layer comprising hafnium silicon oxide on the lower electrode, wherein the method comprises:
(i) applying a first reactant comprising a hafnium precursor to a substrate;
(ii) chemisorbing a first portion of the first reactant and physisorbing a second portion of the first reactant on the substrate;
(iii) applying a first oxidizer to the substrate;
(iv) chemically reacting the first oxidizer with the first portion of the first reactant to form a first solid material comprising hafnium oxide on the substrate;
(v) applying a second reactant comprising a silicon precursor to the first solid material;
(vi) chemisorbing a first portion of the second reactant and physisorbing a second portion of the second reactant on the first solid material;
(vi) applying a second oxidizer to the first solid material; and
(vii) chemically reacting the second oxidizer with the first portion of the second reactant to form a second solid material comprising silicon oxide on the first solid material, wherein the method comprises an atomic layer deposition (ALD) process to form a dielectric layer comprising hafnium silicon oxide on the lower electrode; and
c) forming an upper electrode on the dielectric layer.

22. The method of claim 21, wherein the hafnium precursor comprises tetrakis ethyl methyl amino hafnium (TEMAH, Hf[NC₂H₅CH₃]₄).

23. The method of claim 21, wherein the silicon precursor comprises tetrakis ethyl methyl amino silicon (TEMAS, Si[N(CH₃)C₂H₅]₄).

24. The method of claim 21, wherein the method of forming the dielectric layer further comprises:
a) removing the second portion of the first reactant from the substrate;
b) removing a portion of unreacted first oxidizer from the substrate;
c) removing the second portion of the second reactant; and
d) removing a portion of unreacted second oxidizer from the substrate, wherein (a) through (d) are performed using an inactive gas independently comprising argon, nitrogen, neon, helium, carbon dioxide or mixtures thereof.

25. The method of claim 21, wherein the first and second oxidizers independently comprise O₃, H₂O, H₂O₂, CH₃OH, C₂H₅OH or combinations thereof.

26. The method of claim 21, wherein the method is performed at a temperature in a range of about 150° C. to about 400° C.

27. The method of claim 21, wherein (i) through (iv) and/or (v) through (vii) are performed at least once.
